(19) United States
(12) Patent Application Publication
(10) Pub. No.: US 2016/0145766 A1
(43) Pub. Date: May 26, 2016

(54) EPITAXIAL REACTOR

(71) Applicant: LG SILTRON INCORPORATED, Gyeongsangbuk-do (KR)

(72) Inventor: In Kyum KIM, Gumi-si (KR)

(21) Appl. No.: 14/904,943

(22) PCT Filed: Jul. 8, 2014
(86) PCT No.: PCT/KR2014/006096

§ 371 Date: Jan. 13, 2016

(30) Foreign Application Priority Data
Jul. 19, 2013 (KR) 10-2013-0085222

(51) Int. Cl. C30B 25/14; C23C 16/455

(52) U.S. Cl. CPC C30B 25/14; C23C 16/45591

(57) ABSTRACT

An embodiment comprises: a reaction chamber; a susceptor positioned in the reaction chamber such that a wafer is seated thereon; and a gas flow controller for controlling the flow of gas flowing into the reaction chamber, wherein the gas flow controller comprises an inject cap having a plurality of outlets for separating the flow of gas, an inject buffer comprising first through-holes corresponding to the plurality of outlets, respectively, the first through-holes allowing passage of gas discharged from the plurality of outlets, and a baffle comprising second through-holes corresponding to the first through-holes, respectively, the second through-holes allowing passage of gas that has passed through the first through-holes, and the area of each of the first through-holes is larger than the area of each of the second through-holes and smaller than the area of each of the outlets.

### TECHNICAL FIELD

Embodiments relate to an epitaxial reactor.

### BACKGROUND ART

Epitaxial reactors are classified into batch type epitaxial reactors and single wafer processing type epitaxial reactors, and these single wafer processing type epitaxial reactors are mainly used to manufacture epitaxial wafers having diameters of 200 mm or more.

Such a single wafer processing type epitaxial reactor is configured such that one wafer is seated on a susceptor in a reaction container, after which source gas is made to flow from one side of the reaction container to the other side thereof in a horizontal direction, thereby supplying the source gas to the surface of the wafer and growing an epilayer thereon.

In the single wafer processing type epitaxial reactor, the flow rate or flow distribution of source gas in the reaction container are critical factors for uniform izing the thickness of the layer growing on the surface of the wafer.

A typical epitaxial reactor may include a gas supply part for supplying source gas into a reaction container, and the flow rate or flow distribution of source gas in the reaction container may depend on the flow rate or flow distribution of the source gas supplied from the gas supply part.

In general, the gas supply part may include a baffle having therein a plurality of holes in order to supply source gas to the reaction container such that the source gas may uniformly flow on the surface of the wafer.

### DISCLOSURE

### Technical Problem

Embodiments provide an epitaxial reactor capable of minimizing the loss of source gas introduced into a reaction chamber and the formation of vortices therein, and of increasing the uniformity of thickness of a growing epilayer.

### Technical Solution

In accordance with an embodiment, an epitaxial reactor includes a reaction chamber, a susceptor located in the reaction chamber such that a wafer is seated thereon, and a gas flow controller for controlling a flow of gas introduced into the reaction chamber, wherein the gas flow controller includes an inject cap having a plurality of outlets for separating the flow of gas, an inject buffer having first through-holes corresponding to the respective outlets so that the gas discharged from the outlets passes through the first through-holes, and a baffle having second through-holes corresponding to the respective first through-holes so that the gas passing through the first through-holes passes through the second through-holes, and each of the first through-holes has an area greater than that of each of the second through-holes and smaller than that of each of the outlets.

The epitaxial reactor may further include an insert including a plurality of sections isolated from each other so that the gas passing through the second through-holes passes through the sections, and each of the first through-holes may be aligned with a corresponding one of the sections.

The epitaxial reactor may further include a liner having a stepped part in order to guide the gas passing through the sections to the reaction chamber.

Each of the sections may have an opening area greater than that of each of the first through-holes and that of each of the second through-holes and smaller than that of each of the outlets.

The inject cap may include at least two parts isolated from each other, and one of the outlets may be provided in a corresponding one of the at least two parts.

The inject cap may include a cavity formed in one surface thereof, the cavity being configured of a sidewall and a bottom, a space between the other surface of the inject cap and the bottom of the cavity may be partitioned into first to third parts of the inject cap, the outlets may be provided in the bottom of the cavity, and the inject buffer and the baffle may be sequentially inserted into the cavity such that the first and second through-holes face the bottom of the cavity.

One surface of the baffle may come into contact with the inject buffer, and the other surface of the baffle may be flush with one surface of the inject cap.

A ratio between an area of each of the second through-holes and an area of the associated first through-hole may be 1:5 to 1:20.

The number of second through-holes corresponding to the respective sections may be larger than that of first through-holes corresponding to the respective sections.

The inject cap may be partitioned into two or more parts isolated from each other, and one of the outlets may be provided in a corresponding one of the two or more parts.

The sections may each be aligned with the second through-holes corresponding to the associated first through-hole.

The number of second through-holes corresponding to the respective sections may be larger than that of first through-holes corresponding to the respective sections.

The first through-holes may be arranged at intervals in a longitudinal direction of the inject buffer.

The second through-holes may be arranged at intervals in a longitudinal direction of the baffle.

Each of the first through-holes may have an opening area of 100 to 200 mm².

Each of the second through-holes may have an opening area of 10 to 20 mm².

Outer peripheral surfaces of the inserted inject buffer and baffle may be pressed against an inner surface of the cavity.

The cavity may have a depth similar to a sum of a thickness of the inject buffer and a thickness of the baffle.

### Advantageous Effects

Embodiments can minimize the loss of source gas introduced into a reaction chamber and the formation of vortices therein, and can increase the uniformity of thickness of a growing epilayer.

### DESCRIPTION OF DRAWINGS

FIG. 1 is a cross-sectional view illustrating an epitaxial reactor according to an embodiment.

FIG. 2 is a top view of a gas supply unit illustrated in FIG. 1.

FIG. 3 is a perspective view of the gas supply unit illustrated in FIG. 1.

FIG. 4 is a view for explaining the arrangement of first and second through-holes illustrated in FIG. 1.

FIG. 5 is a view illustrating the size of one first through-hole illustrated in FIG. 1.

FIG. 6A is an exploded perspective view of an inject cap, an inject buffer, and a baffle illustrated in FIG. 1.

FIG. 6B is an assembled perspective view of the inject cap, the inject buffer, and the baffle illustrated in FIG. 1.

FIG. 7 is a cross-sectional view illustrating the assembled state of FIG. 6B when viewed from direction “A-B”.

FIG. 8 is a view illustrating the flow of source gas when a typical epitaxial reactor includes an inject cap and a baffle.

FIG. 9 is a view illustrating the flow of source gas when the epitaxial reactor of the embodiment includes the inject cap, the inject buffer, and the baffle.

### BEST MODE

Reference will now be made in detail to the exemplary embodiments of the present disclosure, examples of which are illustrated in the accompanying drawings. It will be understood that when a layer (film), a region, a pattern, or an element is referred to as being “on” or “under” another layer (film), region, pattern, or, element, it can be directly on/under the layer, region, pattern, or, element, and one or more intervening elements may also be present. When an element is referred to as being “on” or “under”, “under the element” as well as “on the element” can be included based on the element.

In the drawings, the size of each layer is exaggerated, omitted, or schematically illustrated for convenience of description and clarity. Also, the size of each constituent element does not entirely reflect the actual size thereof. In addition, the same reference numbers will be used throughout the drawings to refer to the same or like parts. Hereinafter, an epitaxial reactor according to embodiments will be described with reference to the accompanying drawings.

FIG. 1 is a cross-sectional view illustrating an epitaxial reactor 100 according to an embodiment.

Referring to FIG. 1, the epitaxial reactor 100 may be a single wafer processing type epitaxial reactor which processes semiconductor wafers one by one, and may include a reaction chamber 105 configured of a lower dome 103 and an upper dome 104, a susceptor 120, a susceptor support unit 125, a lower ring 130, an upper ring 135, a liner 140, a preheating ring 150, a gas supply unit 160, and a gas discharge unit 170.

The lower and upper domes 103 and 104 may be located so as to face each other in the vertical direction, and each may be made a transparent material such as quartz glass. The reaction chamber 105 in which an epitaxial reaction occurs may be formed in a space between the lower and upper domes 103 and 104. The reaction chamber 105 may have a gas introduction port 106 formed at one side thereof such that source gas is introduced through the gas inlet port 106, and a gas discharge port 107 formed at the other side thereof such that the introduced source gas is discharged through the gas discharge port 107.

The susceptor 120 may be a support plate having a flat circular shape. The susceptor 120 may be disposed within the reaction chamber 105, and a wafer W may be seated on the upper surface of the susceptor 120. The susceptor 120 may be made of carbon graphite or a material in which carbon graphite is coated with silicon carbide.

The susceptor support unit 125 may be disposed beneath the susceptor 120 to support the susceptor 120, and may move the susceptor 120 vertically within the reaction chamber 105. The susceptor support unit 125 may include a tripodal shaft which supports the lower surface of the susceptor 120.

The liner 140 may be disposed so as to surround the susceptor 120. The liner 140 may have a first stepped part 142 formed at one side of the upper end of the outer peripheral surface thereof for introducing gas into the reaction chamber 105, and a second stepped part 144 formed at the other side of the upper end of the outer peripheral surface thereof for discharging the gas from the reaction chamber 105. The upper portion of the outer peripheral surface of the liner 140 may be flush with the upper surface of the susceptor 120 or the upper surface of the wafer W.

The lower ring 130 may be disposed so as to surround the liner 140, and may have a ring shape. One end 11 of the outer peripheral portion of the lower dome 103 may be pressed against and fixed to the lower ring 130.

The upper ring 135 may be located above the lower ring 130, and may have a ring shape. One end 12 of the outer peripheral portion of the upper dome 104 may be pressed against and fixed to the upper ring 135. Each of the lower and upper rings 130 and 135 may be made of quartz (SiO₂) or silicon carbide (SiC).

The preheating ring 150 may be disposed along the inner peripheral surface of the liner 140 adjacent to the susceptor 120 so as to be flush with the upper surface of the susceptor 120 or the upper surface of the wafer W.

The gas supply unit 160 supplies source gas into the reaction chamber 105 from the outside.

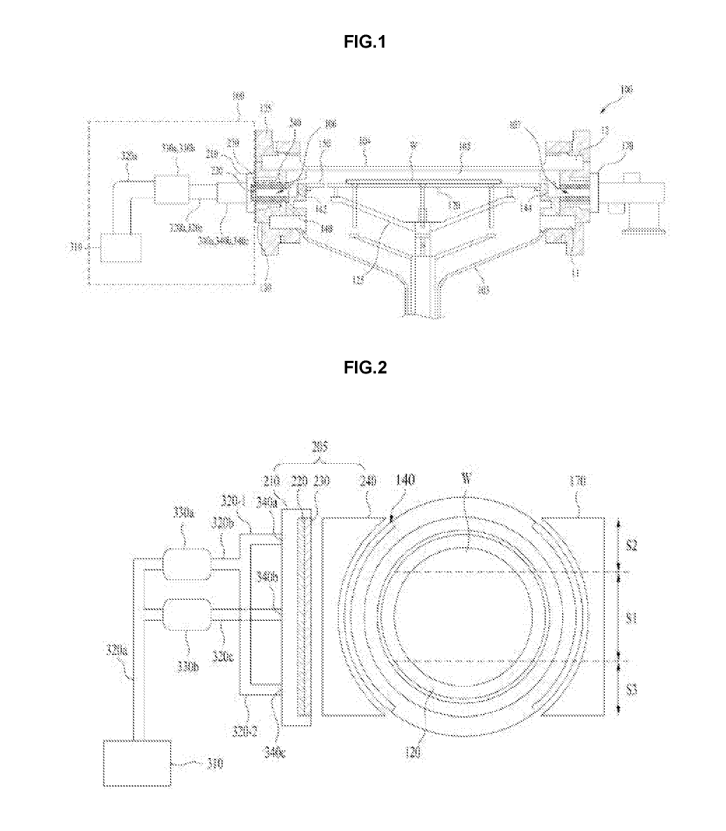

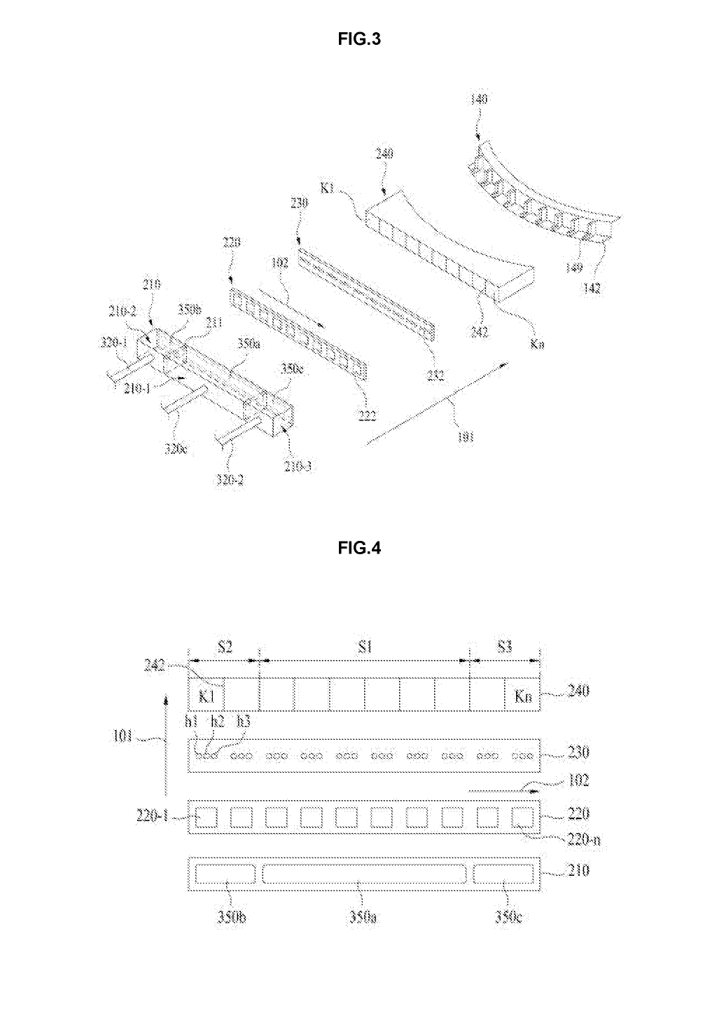

FIG. 2 is a top view of the gas supply unit 160 illustrated in FIG. 1. FIG. 3 is an exploded perspective view of the gas supply unit 160 illustrated in FIG. 1.

Referring to FIGS. 2 and 3, the gas supply unit 160 may include a gas generation part 310, a plurality of gas pipes (e.g., 320a, 320b, and 320c), gas regulation parts 330a and 330b, and a gas flow controller 205.

The gas flow controller 205 (see FIG. 2) includes an inject cap 210, an inject buffer 220, a baffle 230, and an insert 240.

The gas generation part 310 may generate source gas. For example, the source gas may be silicon compound gas such as SiHCl₃, SiCl₄, SiH₂Cl₂, SiH₄, and Si₂H₆, dopant gas such as B₂H₆ and PH₃, carrier gas such as H₂, N₂, and Ar, or the like.

The source gas generated by the gas generation part 310 may be supplied to the inject cap 210 through the gas pipes (e.g., 320a, 320b, and 320c).

The gas regulation parts 330a and 330b may regulate an amount of gas that is supplied to or flows in at least one of the gas pipes (e.g., 320a, 320b, and 320c), and may independently control the flow of source gas supplied to each of a central region S1 and edge regions S2 and S3 of the wafer W. The gas regulation parts 330a and 330b may be embodied, for example, by a mass flow controller.

The source gas generated by the gas generation part 310 may be individually supplied to a plurality of parts of the inject cap 210 through the gas pipes (e.g., 320a, 320b, and 320c). In this case, the number of gas pipes and the number of parts are not limited to those illustrated in FIG. 2, but may be two or more.

At least one (e.g., 320a or 320b) of the gas pipes (e.g., 320a, 320b, and 320c) may be divided into two or more gas pipes. The source gas may be supplied to the inject cap 210 through the divided gas pipes and the non-divided gas pipe.

For example, a first gas pipe 320a may be divided into a second gas pipe 320b and a third gas pipe 320c in order to individually supply source gas (or reaction gas) to each of the central region S1 and edge regions S2 and S3 of the wafer. In addition, the second gas pipe 320b may be divided into two gas pipes in order to individually supply source gas to each of both edge regions S2 and S3 of the wafer and then supply the source gas to the inject cap.

The inject cap 210, the inject buffer 220, the baffle 230, and the insert 240 may be sequentially arranged between a plurality of gas pipes (e.g., 320-1, 320-2, and 320c) and the liner 140. The source gas supplied from the gas pipes (e.g., 320-1, 320-2, and 320c) may flow through the inject cap 210, the inject buffer 220, the baffle 230, and the insert 240 in turn.

The inject cap 210 may include a plurality of gas inlets (e.g., 340a, 340b, and 340c), through which source gas is introduced from the gas pipes (e.g., 320-1, 320-2, and 320c), and a plurality of gas outlets (e.g., 350a, 350b, and 350c) through which the introduced source gas is discharged.

The inject cap 210 may be partitioned into at least two parts (e.g., 210-1, 210-2, and 210-3) which are isolated from each other. Any one of the gas outlets (e.g., 350a, 350b, and 350c) may be provided in a corresponding one of the at least two parts (e.g., 210-1, 210-2, and 210-3). Although the inject cap 210 is depicted as being partitioned into three parts 210-1, 210-2, and 210-3 in FIGS. 1 and 2, the present disclosure is not limited thereto.

For example, a first part 210-1 may be located at the center of the inject cap so as to correspond to or be aligned with the central region S1 of the wafer W, and the gas inlet 340b and the gas outlet 350a may be formed in the first part 210-1.

For example, a second part 210-2 may be located at one side of the first part 210-1 so as to correspond to or be aligned with a first edge region S2 positioned at one side of the central region S1 of the wafer W, and the gas inlet 340a and the gas outlet 350b may be formed in the second part 210-2.

For example, a third part 210-3 may be located at the other side of the first part 210-1 so as to correspond to or be aligned with a second edge region S3 positioned at the other side of the central region S1 of the wafer W, and the gas inlet 340c and the gas outlet 350c may be formed in the third part 210-3.

The inject cap 210 may include partitions between the adjacent parts for partitioning them. For example, the inject cap 210 may include a first partition 211 for partitioning the first and second parts 210-1 and 210-2, and a second partition 212 for partitioning the first and third parts 210-1 and 210-3. Source gas may independently flow in each of the parts (e.g., 210-1, 210-2, and 210-3) owing to the partitions (e.g., 211 and 212).

The inject buffer 220 is disposed adjacent to one end of the inject cap 210, and may have therein a plurality of first through-holes 222 that correspond to or are aligned with first to third gas outlets 350a, 350b, and 350c, respectively.

The first through-holes 222 may face the first to third gas outlets 350a, 350b, and 350c, and the source gas flowing out of the first to third gas outlets 350a, 350b, and 350c may pass through the first through-holes 222.

The baffle 230 is disposed adjacent to one end of the inject buffer 220, and may have therein a plurality of second through-holes 232 that correspond to or are aligned with the respective first through-holes 222.

The second through-holes 232 may face the first through-holes 222, and the source gas flowing out of the first through-holes 222 may pass through the second through-holes 232.

The insert 240 may be disposed so as to be inserted between the lower ring 130 and the upper ring 135, and may include a plurality of sections k1 to kn (n being a natural number greater than 1) through which gas may pass.

The insert 240 may include each partition wall 242 located between two adjacent sections, and the sections k1 to kn (n being a natural number greater than 1) may each be independent and may be isolated from each other by the partition walls 242.

The respective sections k1 to kn (n being a natural number greater than 1) may correspond to or be aligned with the second through-holes 232 corresponding to the associated first through-holes, and the source gas flowing out of the second through-holes 232 may pass through the sections k1 to kn.

The number of second through-holes 232 that correspond to or are aligned with the respective sections k1 to kn (n being a natural number greater than 1) may be larger than the number of first through-holes 222 that correspond to or are aligned with the respective sections k1 to kn (n being a natural number greater than 1).

The first stepped part 142 of the liner 140 may be provided with partition walls 149 corresponding to the partition walls 242 for partitioning the sections k1 to kn (n being a natural number greater than 1). The source gas passing through the sections k1 to kn (n being a natural number greater than 1) may flow along the surface of the first stepped part 142 of the liner 140 which is separated or partitioned by the partition walls 149. The source gas introduced into the reaction chamber 105 through the surface of the first stepped part 142 flows along the surface of the wafer W. The source gas passing through the surface of the wafer W flows to the gas discharge unit 170 through the second stepped part 144 of the liner 140.

FIG. 4 is a view for explaining the arrangement of first through-holes 220-1 to 220-n and second through-holes h1 to hm illustrated in FIG. 1.

Referring to FIG. 4, the first through-holes 220-1 to 220-n (n being a natural number greater than 1) may be arranged at intervals in a longitudinal direction 102 of the inject buffer 220.

Each of the first through-holes 220-1 to 220-n (n being a natural number greater than 1) may be aligned with a corresponding one of the sections k1 to kn (n being a natural number greater than 1) in a first direction 101. The first direction 101 may be a direction oriented toward the insert 140 from the inject buffer 220, or oriented in the width direction of the inject buffer 220.

For example, the number of first through-holes that correspond to or are aligned with each of the sections k1 to kn (n being a natural number greater than 1) may be one.

The second through-holes h1 to hm (m being a natural number greater than 1) may be aligned with a corresponding one of the first through-holes 220-1 to 220-n (n being a natural number greater than 1) in the first direction 101.

The second through-holes (e.g., h1 to hm, where m is a natural number greater than 1) aligned with the first through-holes may be arranged at intervals in the longitudinal direction of the baffle 230.

For example, the number of second through-holes h1 to hm (e.g., m=3) that correspond to or are aligned with one first through-hole (e.g., 220-1) may be two or more.

FIG. 5 is a view illustrating the size of one first through-hole illustrated in FIG. 1.

Referring to FIG. 5, each of the first through-holes 220-1 to 220-n (n being a natural number greater than 1) may have a polygonal shape or a circular shape, but the present disclosure is not limited thereto. For example, the first through-holes may have different shapes.

Each of the first to third gas outlets 350a, 350b, and 350c of the inject cap 210 may have an opening area which is greater than that of each of the first through-holes 220-1 to 220-n (n being a natural number greater than 1).

Each of the first through-holes 220-1 to 220-n (n being a natural number greater than 1) may have an area which is greater than that of each of the second through-holes h1 to hm (m being a natural number greater than 1).

Each of the sections k1 to kn (n being a natural number greater than 1) of the insert 240 may have an opening area, which is greater than that of each of the first through-holes 220-1 to 220-n (n being a natural number greater than 1) and that of each of the second through-holes h1 to hm (m being a natural number greater than 1), and smaller than that of each of the first to third gas outlets 350a, 350b, and 350c.

For example, each of the sections k1 to kn (n being a natural number greater than 1) may have an opening area of 400 to 500 mm², and preferably an opening area of 421 to 484 mm².

The ratio between the area of the second through-hole (e.g., h1) and the area of the first through-hole (e.g., 220-1) may be 1:5 to 1:20, and preferably 1:10.

Each of the first through-holes 220-1 to 220-n (n being a natural number greater than 1) may have an opening area of 100 to 200 mm², and each of the second through-holes h1 to hm (m being a natural number greater than 1) may have an opening area of 10 to 20 mm².

The distance d between two adjacent first through-holes may range from 10 to 15 mm.

A portion 221 (see FIG. 5) between two adjacent first through-holes may correspond to or be aligned with an associated partition wall 242 of the insert 240.

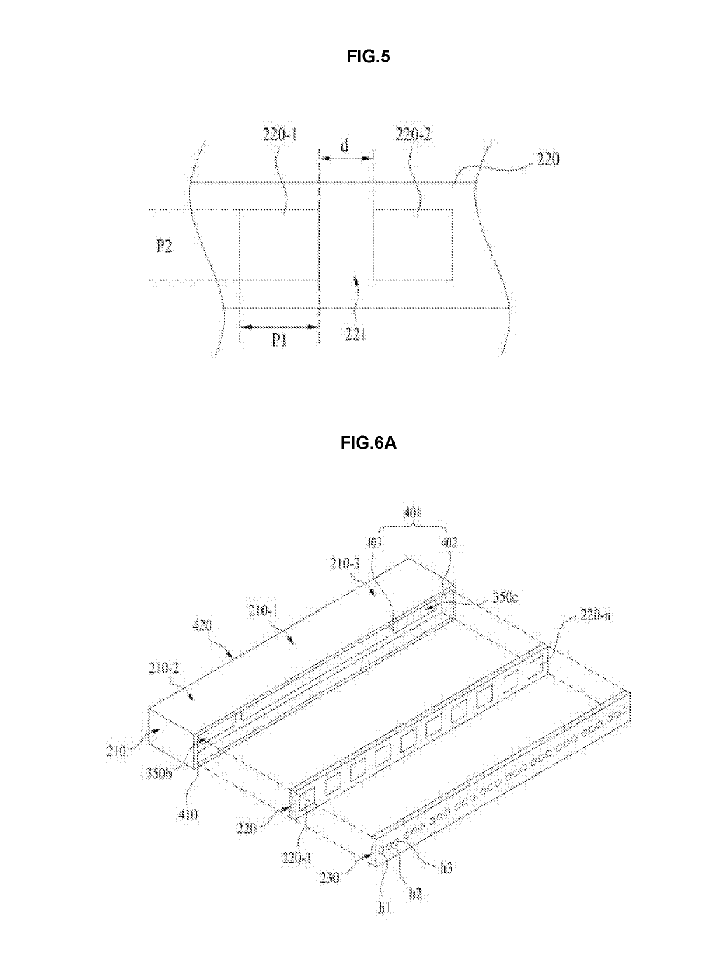

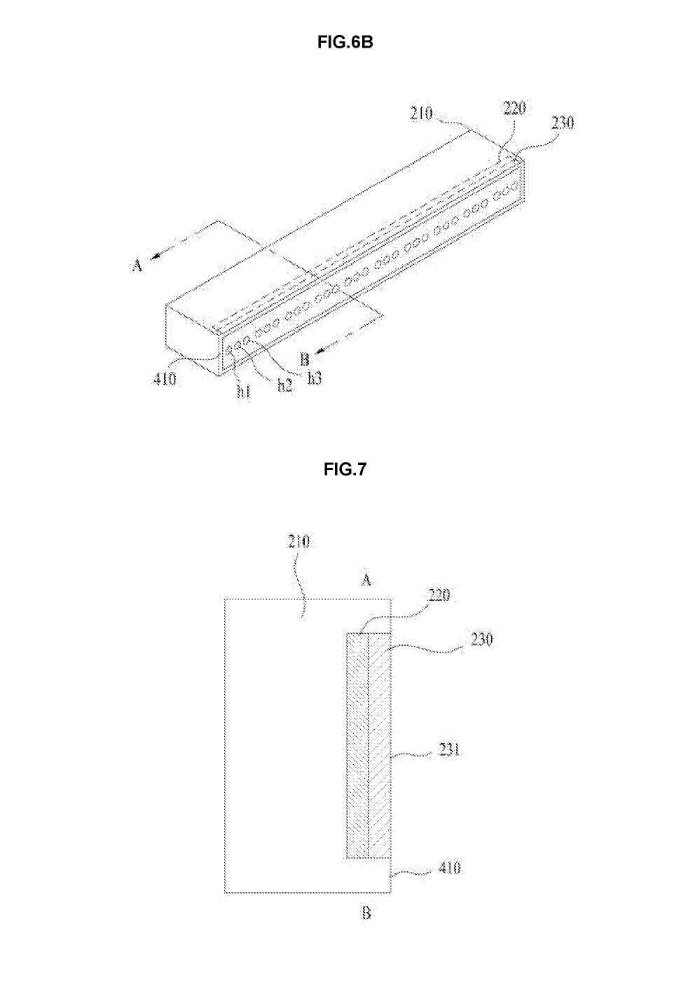

FIG. 6A is an exploded perspective view of the inject cap 210, the inject buffer 220, and the baffle 230 illustrated in FIG. 1. FIG. 6B is an assembled perspective view of the inject cap 210, the inject buffer 220, and the baffle 230 illustrated in FIG. 1.

Referring to FIGS. 6A and 6B, the inject cap 210 may have a cavity 401 in one surface 410 thereof. The cavity 401 may be recessed from one surface 410 of the inject cap 210, and may include a sidewall 402 and a bottom 403.

A space for accommodating the source gas supplied from the gas pipes 320-1, 320-2, and 320-3 may be provided between the other surface 420 of the inject cap 210 and the bottom 403 of the cavity 401. The space may be partitioned into the parts 210-1, 210-2, and 210-3 separated by the partitions 211 and 212.

The gas outlets 350a, 350b, and 350c may be provided in the bottom 403 of the cavity 401. For example, the gas outlets 350a, 350b, and 350 may be formed in the bottom 403 in the state in which they are spaced apart from each other in the longitudinal direction of the inject cap 210.

The inject buffer 220 and the baffle 230 may be sequentially inserted into the cavity 401 such that the first through-holes 220-1 to 220-n (n being a natural number greater than 1) and the second through-holes h1 to hm (m being a natural number greater than 1) face the bottom 403 of the cavity 401.

Each of the inject buffer 220 and the baffle 230 may have a shape such that it may be inserted into the cavity 401, and the outer peripheral surfaces of the inserted inject buffer 220 and baffle 230 may be pressed against the inner surface of the cavity 401.

Since the inject buffer 220 and the baffle 230 are inserted into the inject cap 210 in the embodiment, the inject buffer 220 and the baffle 230 may be stably fixed to the inject cap 210. In addition, since the outer peripheral surfaces of the inserted inject buffer 220 and baffle 230 are pressed against the inner surface of the cavity 401, it is possible to prevent vortices from being formed when source gas passes through the inject cap 210, the inject buffer 220, and the baffle 230 in turn.

The inject buffer 220 may be inserted into the cavity 401 such that the first through-holes 220-1 to 220-n (n being a natural number greater than 1) face the bottom 403 of the cavity 401. The inserted inject buffer 220 may come into contact with the bottom 403 of the cavity 401.

The baffle 230 may be inserted into the cavity 401 such that the second through-holes h1 to hm (m being a natural number greater than 1) face the bottom 403 of the cavity 401. The inserted baffle 230 may come into contact with the inject buffer 220.

The cavity 401 may have a depth similar to the sum of the thickness of the inject buffer 220 and the thickness of the baffle 230, but the present disclosure is not limited thereto.

FIG. 7 is a cross-sectional view illustrating the assembled state of FIG. 6B when viewed from direction “A-B”.

Referring to FIG. 7, one surface of the baffle 230 inserted into the cavity 401 may come into contact with the inject buffer 220, and the other surface 231 of the baffle 230 exposed from the cavity 401 may be flush with one surface 410 of the inject cap 210. However, the present disclosure is not limited thereto.

In general, the source gas supplied from the gas pipes may be introduced into the reaction chamber via the inject cap, the baffle, the insert, and the liner in turn.

However, if the epitaxial reactor includes only a baffle without the inject buffer 220, the second through-holes in the baffle have areas that are much smaller than the areas of the gas outlets in the inject cap. For this reason, when the source gas passes through the inject cap and the baffle, considerable vortex formation and loss of source gas may result.

The flow rate of the source gas supplied to the central region and edge regions of the wafer may not be uniform due to the considerable vortex formation and the loss of source gas. As a result, it may be difficult to control the thickness profile of the epilayer growing on the wafer.

In the embodiment, since the inject buffer 220 including the first through-holes 220-1 to 220-n (n being a natural number greater than 1), each having an area which is smaller than each area of the gas outlets 350a, 350b, and 350c and greater than each area of the second through-holes, is disposed between the inject cap 210 and the baffle 230, it is possible to minimize the formation of vortices and reduce the loss of source gas.

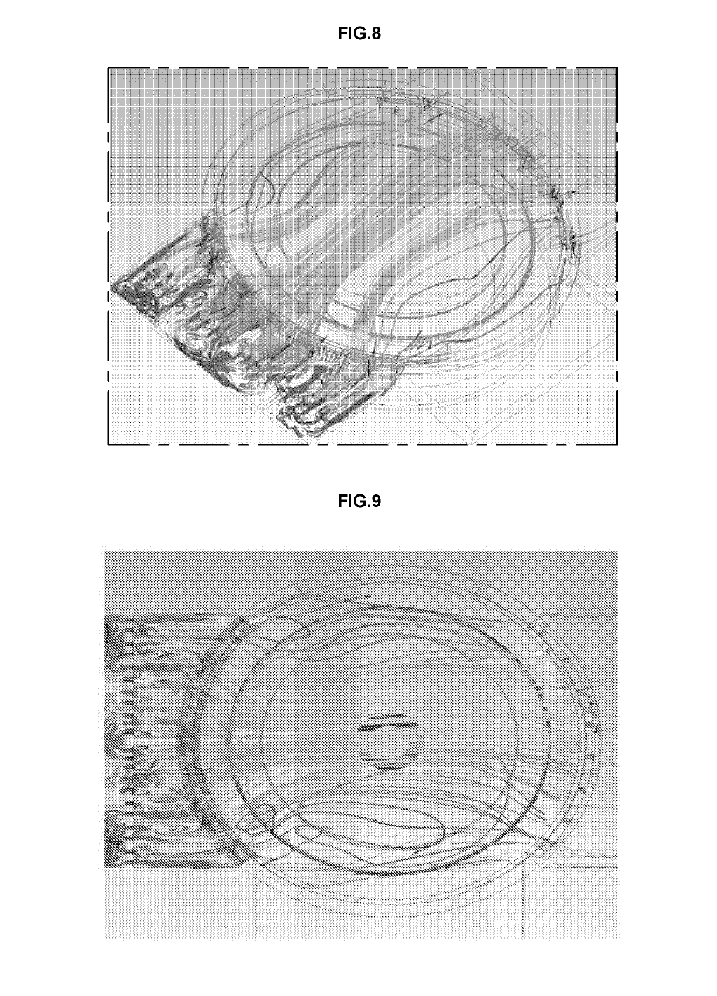

FIG. 8 is a view illustrating the flow of source gas when a typical epitaxial reactor includes an inject cap and a baffle. FIG. 9 is a view illustrating the flow of source gas when the epitaxial reactor of the embodiment includes the inject cap, the inject buffer, and the baffle. FIGS. 8 and 9 illustrate the flow of source gas passing through the gas supply unit and the reaction chamber.

In FIG. 8, it may be seen that vortices are frequently formed and the flow of source gas is concentrated. In contrast, in FIG. 9, it may be seen that vortices are hardly formed and the flow of source gas is uniformly distributed.

Accordingly, since the source gas is uniformly distributed and supplied to the central region S1 and edge regions S2 and S3 of the wafer W in the reaction chamber 105 in the embodiment, it is possible to increase the uniformity of thickness of the growing epilayer.

Particular features, structures, or characteristics described in connection with the embodiment are included in at least one embodiment of the present disclosure and not necessarily in all embodiments. Furthermore, the particular features, structures, or characteristics of any specific embodiment of the present disclosure may be combined in any suitable manner with one or more other embodiments or may be changed by those skilled in the art to which the embodiments pertain. Therefore, it is to be understood that contents associated with such combination or change fall within the spirit and scope of the present disclosure.

### INDUSTRIAL APPLICABILITY

Embodiments are applicable to wafer manufacturing processes.

1. An epitaxial reactor comprising:
a reaction chamber;
a susceptor located in the reaction chamber such that a wafer is seated thereon; and
a gas flow controller for controlling a flow of gas introduced into the reaction chamber,
wherein the gas flow controller comprises:
an inject cap having a plurality of outlets for separating the flow of gas;
an inject buffer having first through-holes corresponding to the respective outlets so that the gas discharged from the outlets passes through the first through-holes; and
a baffle having second through-holes corresponding to the respective first through-holes so that the gas passing through the first through-holes passes through the second through-holes, and
wherein each of the first through-holes has an area greater than that of each of the second through-holes and smaller than that of each of the outlets.

2. The epitaxial reactor according to claim 1, further comprising:
an insert comprising a plurality of sections isolated from each other so that the gas passing through the second through-holes passes through the sections,
wherein each of the first through-holes is aligned with a corresponding one of the sections.

3. The epitaxial reactor according to claim 2, further comprising a liner having a stepped part in order to guide the gas passing through the sections to the reaction chamber.

4. The epitaxial reactor according to claim 2, wherein each of the sections has an opening area greater than that of each of the first through-holes and that of each of the second through-holes and smaller than that of each of the outlets.

5. The epitaxial reactor according to claim 1, wherein:
the inject cap comprises at least two parts isolated from each other; and
one of the outlets is provided in a corresponding one of the at least two parts.

6. The epitaxial reactor according to claim 5, wherein:
the inject cap comprises a cavity formed in one surface thereof, the cavity being configured of a sidewall and a bottom; and
a space between the other surface of the inject cap and the bottom of the cavity is partitioned into first to third parts of the inject cap, the outlets are provided in the bottom of the cavity, and the inject buffer and the baffle are sequentially inserted into the cavity such that the first and second through-holes face the bottom of the cavity.

7. The epitaxial reactor according to claim 6, wherein one surface of the baffle comes into contact with the inject buffer, and the other surface of the baffle is flush with one surface of the inject cap.

8. The epitaxial reactor according to claim 1, wherein a ratio between an area of each of the second through-holes and an area of the associated first through-hole is 1:5 to 1:20.

9. The epitaxial reactor according to claim 2, wherein the number of second through-holes corresponding to the respective sections is larger than that of first through-holes corresponding to the respective sections.

10. The epitaxial reactor according to claim 1, wherein the inject cap is partitioned into two or more parts isolated from each other, and one of the outlets is provided in a corresponding one of the two or more parts.

11. The epitaxial reactor according to claim 2, wherein the sections are each aligned with the second through-holes corresponding to the associated first through-hole.

12. The epitaxial reactor according to claim 2, wherein the number of second through-holes corresponding to the respective sections is larger than that of first through-holes corresponding to the respective sections.

13. The epitaxial reactor according to claim 2, wherein the first through-holes are arranged at intervals in a longitudinal direction of the inject buffer.

14. The epitaxial reactor according to claim 2, wherein the second through-holes are arranged at intervals in a longitudinal direction of the baffle.

15. The epitaxial reactor according to claim 1, wherein each of the first through-holes has an opening area of 100 to 200 mm².

16. The epitaxial reactor according to claim 1, wherein each of the second through-holes has an opening area of 10 to 20 mm².

17. The epitaxial reactor according to claim 6, wherein outer peripheral surfaces of the inserted inject buffer and baffle are pressed against an inner surface of the cavity.

18. The epitaxial reactor according to claim 6, wherein the cavity has a depth similar to a sum of a thickness of the inject buffer and a thickness of the baffle.
